(19) United States
(12) Patent Application Publication
(10) Pub. No.: US 2007/0139055 A1
(43) Pub. Date: Jun. 21, 2007

(54) Electric Circuit Tracing System

(76) Inventor: Clinton E. Cockrill, Oakland, CA (US)

Correspondence Address: QUICKPATENTS, INC., 31877 DEL OBISPO, SUITE 202, SAN JUAN CAPISTRANO, CA, 92675, US

(21) Appl. No.: 11/619,719

(22) Filed: Jan. 4, 2007

Related U.S. Application Data
(60) Provisional application No. 60/756,312, filed on Jan. 5, 2006.

(51) Int. Cl. G01R 19/00; G01R 31/28

(52) U.S. Cl. 324/528; 324/67

(57) ABSTRACT

A testing system for a plurality of electric circuits, such as those, for example, powered by circuit breakers or fuses in a building structure, is disclosed. A receiver module includes a battery-powered microprocessor that includes a radio receiver interconnected with an antenna, as well as a plurality of indicator LEDs. A plurality of transmitter modules is included, each of which includes a microprocessor powered by a transformer connected to at least two power prongs for drawing power from a conventional power outlet, or to a standard light bulb threaded base for drawing power from a conventional light bulb socket. The microprocessor of each transmitter module includes a radio transmitter interconnected with an antenna which transmits a confirmation signal when the transmitter module is receiving power. The confirmation signal of each transmitter module includes a unique differentiating component. As such, the radio receiver of the receiver module detects the confirmation signal and the differentiating component from each transmitter module and thereby distinguishes the confirmation signals of each transmitter module from each other transmitter module. For those transmitter modules for which a confirmation signal is received, the corresponding indicator LED is activated to alert the user which transmitter modules are currently transmitting at any given testing time.

### CROSS-REFERENCE TO RELATED APPLICATIONS

This application claims the benefit of U.S. Provisional Patent Application 60/756,312, filed on Jan. 5, 2006.

### STATEMENT REGARDING FEDERALLY SPONSORED RESEARCH AND DEVELOPMENT

Not Applicable.

### FIELD OF THE INVENTION

This invention relates to electronic circuit testing, and more particularly to a novel system for tracing a plurality of electrical circuits simultaneously.

### DISCUSSION OF RELATED ART

Electricians, homeowners, maintenance personnel and others often need to know which electrical circuit controls a given electrical receptacle, such as a power outlet, light socket, or the like, in a building. Typically, for example, to create a diagram of the building that indicates which electrical receptacles correspond to each circuit breaker or fuse, two workers are typically needed, each having a communication means such as a two-way radio or a cellular phone. While one worker checks the power on a first electrical receptacle, such as by plugging in a lamp or other power-indicating device, the second worker flips on each circuit breaker in turn. When the lamp goes on, the first worker communicates such to the second worker, who then writes down that the first electrical receptacle corresponds to the circuit breaker last switched on. This process continues until all outlets or other electrical receptacles have been accounted for. Such a process is time consuming and, in its most efficient use, requires two workers.

Circuit tracers are known in the prior art to assist in tracing electrical circuits. For example, U.S Pat. No. 6,163,144 to Steber et al. on Dec. 19, 2000, teaches a single transmitter that communicates with a receiver for inducing a modulated tracing signal onto a particular circuit at one electrical receptacle. An inductive pick-up device is used at the circuit breaker box to detect which circuit, based on proximity of the pick-up device to the circuit breaker, controls the electrical receptacle. Such a device does eliminate the need for the circuit breakers to be successively toggled. However, two workers are still required for mapping out the circuit diagram of the entire structure, and two-way communication is still required between them so that information about which electrical receptacle is being used, or which circuit breaker was found to be carrying the tracing signal, can be exchanged.

Clearly, then, there is a need for a system that can relatively quickly allow a single worker to map-out the circuit diagram for an entire structure. Such a needed device would not require a worker to move a device from one electrical receptacle to the next, but rather would allow all electrical receptacles to be traced simultaneously. Further, such a needed system would provide other measured parameters to the user, such as line voltage, line frequency, or the like. The needed system would allow a user to upload the information into a computer or other electrical device, for quickly and accurately completing inspection reports or the like. The present invention accomplishes these objectives.

### SUMMARY OF THE INVENTION

The present device is a testing system for a plurality of electric circuits, such as those, for example, powered by circuit breakers or fuses in a building structure. A receiver module includes a battery-powered microprocessor that includes a radio receiver interconnected with an antenna, as well as a plurality of indicator LEDs. The receiver module further includes an enclosure, preferably having a plurality of erasable writing spaces next to each indicator LED for making notes with a dry-erase pen, removable stickers, or the like.

The system further includes a plurality of transmitter modules, each of which includes a microprocessor powered by a transformer connected to at least two power prongs for engaging a conventional power outlet, or a standard light bulb threaded base for engaging a conventional light bulb socket. The microprocessor of each transmitter module includes a radio transmitter interconnected with an antenna. The radio transmitter transmits a confirmation signal when the microprocessor is receiving power. The confirmation signal of each transmitter module includes a unique differentiating component, such as a coded identifier, a unique frequency, a unique time delay, a unique amplitude, or the like. Each transmitter module includes an enclosure that preferably includes a printed indicia thereon representing its unique coded identifier.

As such, the radio receiver of the receiver module detects the confirmation signal and the differentiating component from each transmitter module and thereby distinguishes the confirmation signals of each transmitter module from each other transmitter module. For those transmitter modules for which a confirmation signal is received, the corresponding indicator LED is activated to alert the user which transmitter modules are currently transmitting.

In an alternate embodiment, each radio transmitter of each transmitter module and the radio receiver of the receiver module are each transceivers. As such, the receiving module transmits a query signal detectable by each transmitter module, and upon detection thereof each transmitter module transmits its confirmation signal. Further, each transmitter module may further include a unique transmitter module identifier programmed therein, each identifier corresponding to exactly one of the transmitter modules. As such, each transmitter module transmits its confirmation signal only upon detection of the query signal having its corresponding identifier. In this manner, each transmitter module may be queried, in succession, and given a suitable duration of time to respond to detect if the transmitter module is powered-up. The indicator LED corresponding to each transmitter is either activated or deactivated according to whether or not the receiver module receives each transmitter module's identifier in the time allowed. Once each transmitter module has been queried, the process begins again.

The present invention is a system that can relatively quickly allow a single worker to map-out the circuit diagram for an entire structure. The present system does not require a worker to move a device from one electrical receptacle to the next, but rather allows all electrical receptacles to be traced substantially simultaneously. Further, the inventive system can provide other measured parameters for the user, such as line voltage, line frequency, or the like, and provides a means by which the user can upload the detected information into a computer or other electrical device. Such a capability is convenient for quickly and accurately completing inspection reports, for example. The present invention accomplishes these objectives. Other features and advantages of the present invention will become apparent from the following more detailed description, taken in conjunction with the accompanying drawings, which illustrate, by way of example, the principles of the invention.

### DESCRIPTION OF THE DRAWINGS

FIG. 1 is a block diagram of a testing system of the present invention, illustrating a receiving module and a plurality of transmitting modules fixed to power outlets within a structure, each transmitter being powered by one of at least one electric circuits;

FIG. 2 is a perspective view of the receiver module of the present invention;

FIG. 3 is a perspective view of a circuit board of the receiver module;

FIG. 4 is a perspective view of the plurality of transmitter modules;

FIG. 5 is a perspective view of a circuit board of one of the plurality of transmitter modules;

FIG. 6 is a schematic diagram of the receiver module; and

FIG. 7 is a schematic diagram of one of the plurality of transmitter modules.

### DETAILED DESCRIPTION OF THE PREFERRED EMBODIMENT

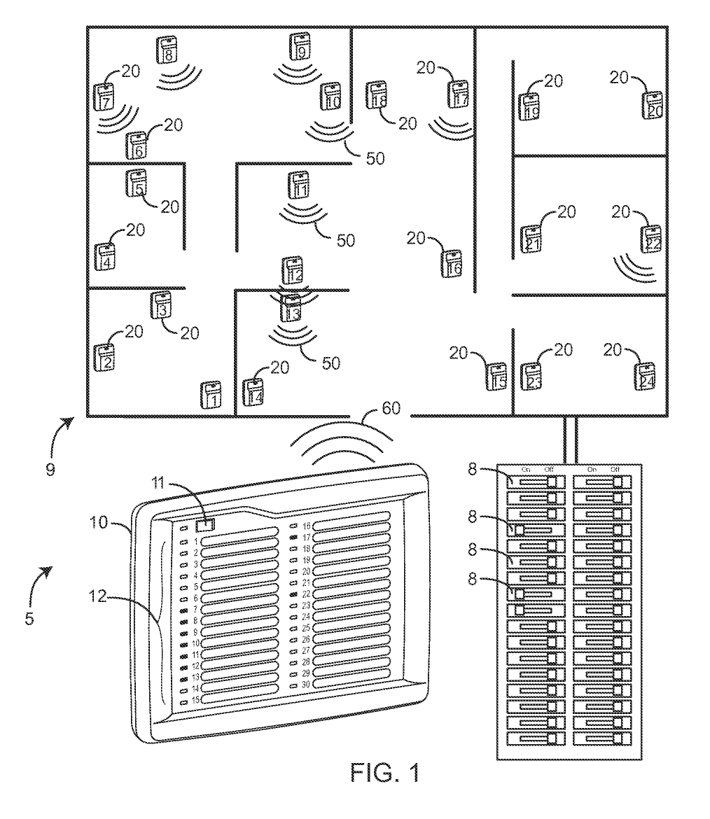

FIG. 1 illustrates a testing system 5 for at least one electric circuit 8, and preferably a plurality of electric circuits 8, such as, for example, a plurality of electrical power circuits 8 in a building structure 9. Each electric circuit 8 is powered by a circuit breaker, fuse, or the like.

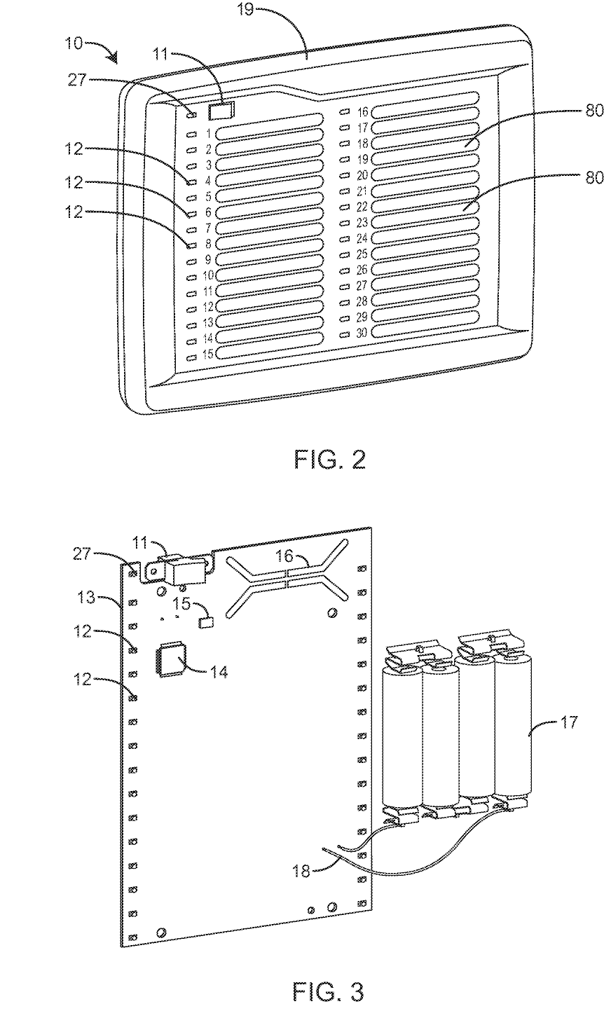

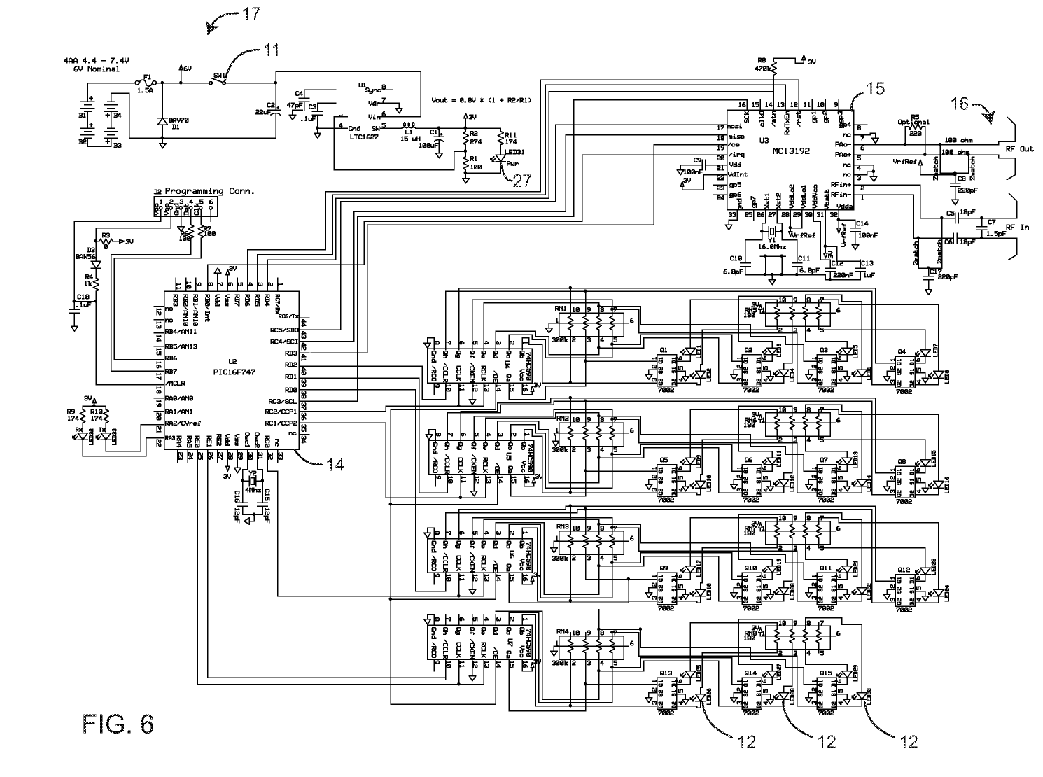

A receiver module 10, illustrated in FIGS. 2 and 3, includes a power means 17, and a microprocessor means 14 powered by the power means 17. The power means 17 is preferably at least one battery, as illustrated in FIG. 3, but can alternately be an AC power source stepped down with a transformer (not shown). The microprocessor means 14 is preferably a micro-controller chip, or the like, such as illustrated in FIG. 3 and in the electrical schematic of FIG. 6. The microprocessor means 14 further includes a radio receiver 15 interconnected with an antenna 16, and a plurality of indicator means 12, such as a plurality of light indicator LEDs or other visual indicators. The microprocessor means 14, the radio receiver 15, the antenna 16, and the plurality of indicator means 12 are, and all associated circuitry is preferably mounted on a circuit board 13 (FIG. 3), which includes a wired connection 18 to the power means 17. A power switch 11 may be included to selectively supply power from the power means 17 to the microprocessor means 14 and related circuitry. A power LED indicator 27 may be included to indicate when the power switch 11 is on. The receiver module 10 further includes an enclosure 19, preferably having a plurality of erasable writing spaces 80 next to each indicator means 12 for making notes with a dry-erase pen, removable stickers, or the like (not shown).

The system 5 further includes a plurality of transmitter modules 20, each of which includes a power means 26 and a microprocessor means 28 powered by the power means 26. The power means 26 preferably includes at least two power prongs 32 (FIG. 5A) for engaging a conventional power outlet (not shown), a standard light bulb threaded base 33 (FIG. 5B) for engaging a conventional light bulb socket (not shown), a pair of wires with alligator clips (not shown), or the like.

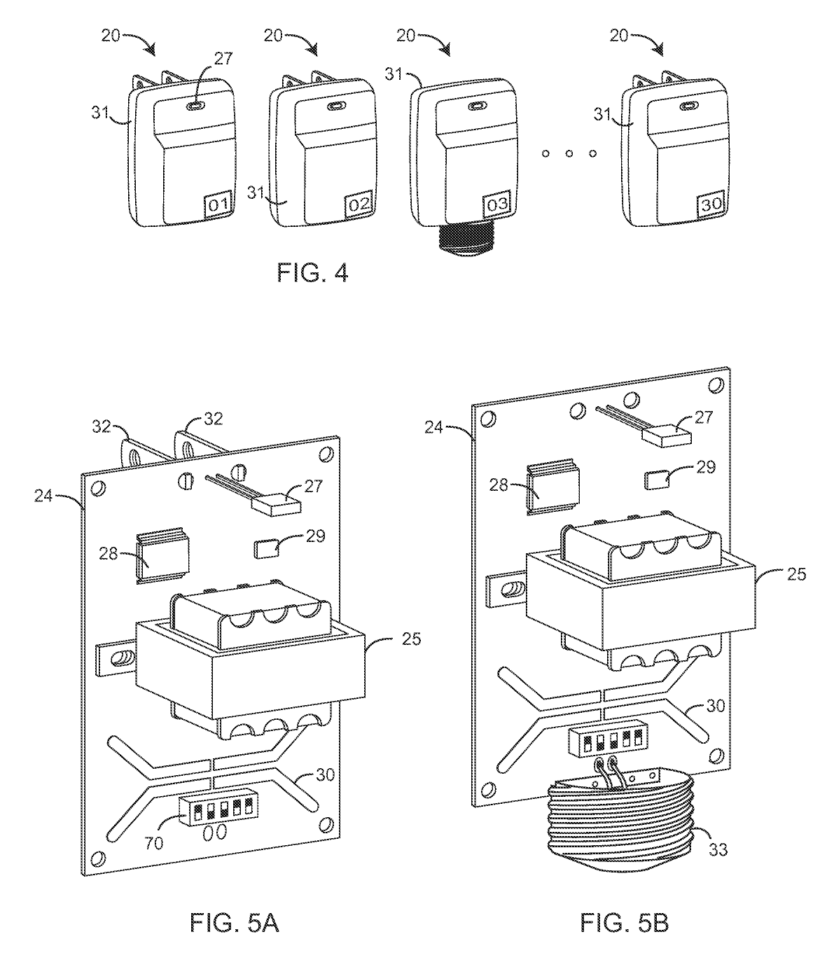

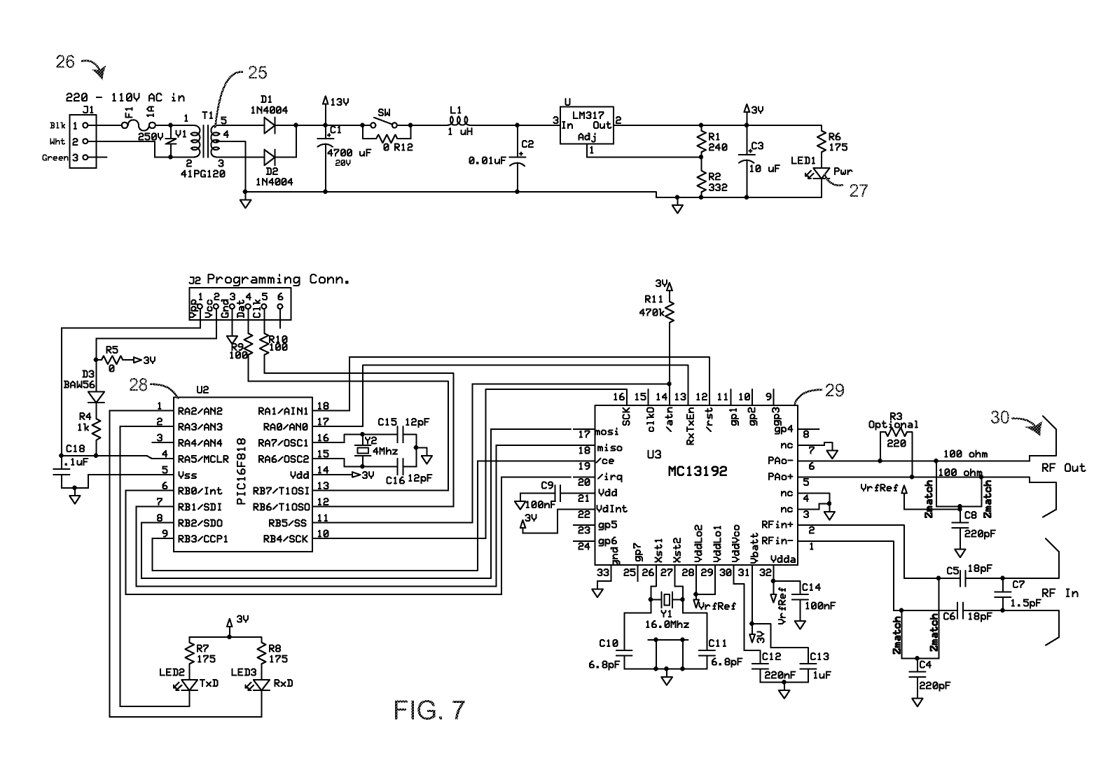

The microprocessor means 28 of each transmitter module 20 is preferably a microcontroller chip, as illustrated in FIGS. 5A, 5B, and 7, and further includes a radio transmitter 29 interconnected with an antenna 30. The radio transmitter 29 transmits a confirmation signal 50 (FIG. 1) when the power means 26 powers the microprocessor means 28. The confirmation signal 50 of each transmitter module 20 includes a unique differentiating component, such as a coded identifier, a unique frequency, a unique time delay, a unique amplitude, or the like (not shown). The microprocessor means 28, the radio transmitter 29, the antenna 30, and all associated circuitry is preferably mounted on a circuit board 24 (FIGS. 5A and 5B). A power LED indicator 27 may be included to indicate when power is being supplied to the microprocessor means 28. Each transmitter module 20 includes an enclosure 31 that preferably includes a printed indicia thereon representing its unique coded identifier (FIG. 4).

As such, the radio receiver 15 of the receiver module 10 detects the confirmation signal 50 and the differentiating component from each transmitter module 20 and thereby distinguishes the confirmation signals 50 of each transmitter module 20 from each other transmitter module 20. For those transmitter modules 20 for which a confirmation signal 50 is received, the corresponding indicator means 12 is activated to alert the user which transmitter modules 20 are currently transmitting.

In an alternate embodiment, each radio transmitter 29 of each transmitter module 20 and the radio receiver 15 of the receiver module 10 are each transceivers. As such, the receiving module 10 transmits a query signal 60 detectable by each transmitter module 20, and upon detection thereof each transmitter module 20 transmits its confirmation signal 50. Further, each transmitter module 20 may further include a unique transmitter module identifier 70 programmed therein, each identifier 70 corresponding to exactly one of the transmitter modules 20. As such, each transmitter module 20 transmits its confirmation signal 50 only upon detection of the query signal 60 having its corresponding identifier 70. In this manner, each transmitter module 20 may be queried, in succession, and given a suitable duration of time to respond, such as 10 to 20 milliseconds, to detect if the transmitter module 20 is powered-up. The indicator means 12 corresponding to each transmitter 20 is either activated or deactivated according to whether or not the receiver module 10 receives each transmitter module's identifier 70 in the time allowed. Once each transmitter module 20 has been queried, the process begins again.

Additionally, each transmitter module 20 may include at least one parameter detection means (not shown), such as a voltage or frequency measurement. Each transmitter module 20, in such an embodiment, transmits its detected measurement of the parameter with its confirmation signal 50, such that the receiver module 20 may obtain a plurality of such measurements from all of the transmitter modules 20 for displaying on a display means, such as LED light bars, LCD displays, a CRT or computer display screen, or the like (not shown), and for diagnosing the state of the electrical circuits 8. Other measured parameters may include air temperature, ambient noise levels, or any other desired parameter. In such an embodiment, the receiver module 10 may further include a memory means (not shown) interconnected with the microprocessor means 14 for storing such parameter measurements of each transmitter module 20, and a memory transferring means (not shown) for transferring the contents of the memory means to an electronic device (not shown), such as a laptop computer or the like.

In use, a user plugs each transmitter module 20 into a power outlet, light socket, or the like, and then activates the receiver module 10. The user then may, in turn, power-up each electric circuit 8 by throwing its associated circuit breaker, connecting its associated fuse, or the like. The receiver module 10 will then, through the means herein described, receive the confirmation signals 50 from each transmitter module 20 that is powered, and indicate such with the indication means 12. The user may then note which circuit 8 corresponds to each transmitter module 20. This process is repeated until each transmitter module 20 is accounted for, each transmitter module 20 corresponding to one circuit 8. In practice, if a single transmitter module 20 is activated by more than one circuit 8, then the user is alerted to this fact and the structure 9 may be checked for errors in wiring. Likewise, if any transmitter modules 20 remain unaccounted for after each circuit 8 has been tested, the structure 9 may be check for wiring errors.

While a particular form of the invention has been illustrated and described, it will be apparent that various modifications can be made without departing from the spirit and scope of the invention. For example, thirty transmitter modules 20 are shown herein, but any number of transmitter modules 20 may be used. Further, a variety of means for uniquely identify each transmitter module 20 have been disclosed, but other suitable means may be used as such become known in the art, without departing from the spirit and scope of the present invention. Accordingly, it is not intended that the invention be limited, except as by the appended claims.

What is claimed is:

1. A testing system for at least one electric circuit, comprising:
a receiver module that includes a power means, a microprocessor means powered by the power means, the microprocessor means including a radio receiver interconnected with an antenna and an indicator means; and
a plurality of transmitter modules, each transmitter module including a power means, a microprocessor means powered by the power means, the microprocessor means including a radio transmitter interconnected with an antenna, the radio transmitter capable of transmitting a confirmation signal having a differentiating component when the power means powers the microprocessor means, the differentiating component being unique for each transmitter module, the radio receiver of the receiver module capable of detecting the confirmation signal from each transmitter module, the receiver module capable of distinguishing the confirmation signals of each transmitter module by its differentiating component;
whereby with at least one transmitter module engaged to and powered by each electric circuit, the receiver module indicates with the indicator means which transmitter modules are sending confirmation signals at any given testing time.

2. The testing system of claim 1 wherein the power means includes a set of power prongs for engaging a power outlet.

3. The testing system of claim 1 wherein the power means includes a standard light bulb threaded base for engaging a conventional light bulb socket.

4. The testing system of claim 1 wherein the indicator means is a plurality of light indicators, each light indicator corresponding to one of the transmitter modules.

5. The testing system of claim 1 wherein the receiver means and transmitter means are each transceivers, and wherein the receiving module transmits a query signal detectable by each transmitter module, and wherein upon detection of the query signal from the receiver module, each transmitter module transmits its confirmation signal.

6. The testing system of claim 5 wherein the query signal of the receiver module includes a transmitter module identifier, each identifier corresponding to exactly one of the transmitter modules, whereupon each transmitter module transmits its confirmation signal only upon detection of the query signal having its corresponding identifier.

7. The testing system of claim 6 wherein the receiver module transmits the query signal for each transmitter module in succession.

8. The testing system of claim 1 wherein the differentiating component of each transmitter module is the frequency of the confirmation signal, whereby the receiver means may identify which transmitter module is transmitting by detecting the frequencies of the received confirmation signals.

9. The testing system of claim 1 wherein the differentiating component of each transmitter module is a unique confirmation signal amplitude, whereby the receiver means may identify which transmitter module is transmitting by detecting the amplitudes of the received confirmation signals.

10. The testing system of claim 5 wherein the query signal of the receiver means is universal, and the differentiating component of each transmitter module is the frequency of the confirmation signal, whereby the receiver means may identify which transmitter module is transmitting by detecting the frequencies of the received confirmation signals.

11. The testing system of claim 5 wherein the query signal of the receiver means is universal, and the differentiating component of each transmitter module is a unique confirmation signal amplitude, whereby the receiver means may identify which transmitter module is transmitting by detecting the amplitudes of the received confirmation signals.

12. The testing system of claim 5 wherein the query signal of the receiver means is universal, and the differentiating component of each transmitter module is a coded identifier, whereby the receiver means may identify which transmitter module is transmitting by detecting the coded identifiers received from the plurality of transmitters.

13. The testing system of claim 5 wherein the query signal of the receiver means is universal, and the differentiating component of each transmitter module is a unique delay time, whereby the receiver means may identify which transmitter module is transmitting by detecting the delay times of the received confirmation signals.

14. The testing system of claim 1 wherein each transmitter module includes at least one parameter detection means, and wherein each transmitter module transmits each parameter measurement with its confirmation signal.

15. The testing system of claim 14 wherein the microprocessor means of the receiver module further includes a memory means for storing the parameter measurements of each transmitter module.

16. The testing system of claim 15 wherein the microprocessor means of the receiver module further includes a memory transferring means for transferring the contents of the memory means to an electronic device.
